(19) United States
(12) Patent Application Publication
(10) Pub. No.: US 2019/0181309 A1
(43) Pub. Date: Jun. 13, 2019

(54) CUTTING METHOD OF SEMICONDUCTOR PACKAGE MODULE AND SEMICONDUCTOR PACKAGE UNIT

(71) Applicant: Yu Shin Prod. Co., Ltd., Hsinchu City (TW)

(72) Inventors: Sheng-Lung Wang, Hsinchu City (TW); Fu-Hao Chan, Hsinchu City (TW)

(73) Assignee: Yu Shin Prod. Co., Ltd., Hsinchu City (TW)

(21) Appl. No.: 15/993,620

(22) Filed: May 31, 2018

(30) Foreign Application Priority Data
Dec. 8, 2017 (CN) 201711297556.1

(51) Int. Cl. H01L 33/54; H01L 33/48; H01L 21/56; H01L 23/31

(52) U.S. Cl. CPC H01L 33/54; H01L 33/483; H01L 2933/0033; H01L 23/3107; H01L 2933/005; H01L 21/561

(57) ABSTRACT

A cutting method of a semiconductor package module and a semiconductor package unit are provided. The cutting method of the semiconductor package module includes steps as follow. A plurality of semiconductor chips are disposed on a substrate, and the semiconductor chips and a surface of the substrate are covered with a packaging layer. A plurality of cutting lines are defined on the surface of the substrate. A plurality of spot-like depressions are formed on the substrate or the packaging layer along the cutting lines by laser. A force is applied to the substrate such that the substrate is broken along the cutting lines and a plurality of semiconductor package units are formed.

### CROSS REFERENCE TO RELATED APPLICATION

This application claims the priority benefit of China application serial no. 201711297556.1, filed on Dec. 8, 2017. The entirety of the above-mentioned patent application is hereby incorporated by reference herein and made a part of specification.

### BACKGROUND OF THE INVENTION

### 1. Field of the Invention

The invention relates to a cutting method of a semiconductor package module and a semiconductor package unit, and mainly adopt laser to cut the semiconductor package module. Power of the laser or the time during which the laser is projected to a substrate or a packaging layer is adjusted during a cutting process to increase the number of the semiconductor package units per unit area, facilitate a yield of the manufacturing process, and reduce a manufacturing cost of the semiconductor package unit.

2. Description of Related Art

Light emitting diodes (LEDs) are known for having a longer lifetime, a smaller size, a lower power consumption, a quick response time, no radiation, and monochromatic light emission, and are thus broadly applied in various products such as indicators, billboards, traffic signal lamps, vehicle lamps, display panels, communication devices, and consumers' electronic products.

Referring to FIGS. 1 and 2, FIGS. 1 and 2 are respectively a side view and a top view illustrating a light emitting diode in the known art. A light emitting diode module 10 includes a substrate 11, a plurality of light emitting diode dies 13 and at least one packaging layer 15. The light emitting diode dies 13 are disposed on the substrate 11, and the packaging layer 15 covers each of the light emitting diode dies 13 on the substrate 11 to form a package 151 and a protection layer 153 on each of the light emitting diode dies 13. Specifically, the package 151 may be in a semi-spherical, planar, or curved structure. In addition to protecting the light emitting diode die 13, the package 151 may also be configured to converge light generated by the light emitting diode die 13.

After the light emitting diodes 13 and the packaging layer 15 are formed, a blade 12 may be adapted to cut the packaging layer 15 and the substrate 11 between two adjacent light emitting diode dies 13. For example, the light emitting diode module 10 may be cut along cutting lines 14 in FIGS. 1 and 2 to thereby form a plurality of light emitting diodes 101.

For the convenience of cutting the light emitting diode module 10 with the blade 12, when the light emitting diode dies 13 are disposed on the substrate 11, a cutting channel 17 is preserved between the adjacent light emitting diode dies 13 in addition to a working width of the protection layer 153, so as to prevent the blade 12 from damaging the package 151 or the light emitting diode die 13 during a cutting process. Due to the presence of the cutting channels 17, the number of the packages 151 available on the substrate 11 is reduced, and the manufacturing cost of the package 151 is consequently higher.

Besides, there may be particles after the light emitting diode module 10 is cut by the blade 12. Therefore, the cut light emitting diodes 101 may need to be washed with water or a cleaning solution. However, during the process of cleaning the light emitting diodes 101, the packaging layer 15 or the remaining protection layer 153 on the substrate 11 may be detached, and the yield of the light emitting diodes 101 is thus reduced.

### SUMMARY OF THE INVENTION

The embodiments of the invention provides a cutting method of a semiconductor package module and a semiconductor package unit using the same. According to the embodiments of the invention, laser is adopted to cut the semiconductor package module. Compared with cutting a substrate or a packaging layer with a blade, the embodiments of the invention are able to reduce the area of cutting channels preserved on a substrate to facilitate the number of the semiconductor package units per unit area and reduce a manufacturing cost of the semiconductor package unit.

A cutting method of a semiconductor package module according to the embodiments of the invention adopts laser to cut a semiconductor package module. When a semiconductor package is cut with laser, the power of the laser or the time during which the laser is projected to a substrate or a packaging layer may be adjusted to reduce the chance that a packaging layer is burned by the laser during a cutting process, which affects the yield and the reliability of the semiconductor package unit.

An embodiment of the invention provides a cutting method of a semiconductor package module. The cutting method includes steps as follow. A plurality of semiconductor chips are disposed on a surface of a substrate. The semiconductor chips disposed on the surface of the substrate are covered with a packaging layer. Laser is projected to the substrate or the packaging layer between two adjacent semiconductor chips, and a plurality of spot-like depressions are formed on the substrate or the packaging layer. In addition, a force is applied to the substrate to break the substrate along the spot-like depressions and form a plurality of semiconductor package units.

Another embodiment of the invention provides another cutting method of a semiconductor package module. The cutting method includes steps as follow. A plurality of semiconductor chips are disposed on a surface of a substrate. The semiconductor chips on the surface of the substrate are covered with a packaging layer. A plurality of cutting lines are defined on the surface of the substrate based on positions of the semiconductor chips, wherein each of the cutting lines is located between two semiconductor chips and includes a plurality of cutting sections. Laser is sequentially projected on the substrate or the packaging layer in non-adjacent cutting sections, and a plurality of cutting marks are sequentially formed on the substrate or the packaging layer in the non-adjacent cutting sections until the cutting marks are formed on all the cutting lines by the laser. In addition, a force is applied to the substrate to break the substrate along the cutting marks and form a plurality of semiconductor package units.

Another embodiment of the invention provides another cutting method of a semiconductor package module. The cutting method includes steps as follow. A packaging layer is disposed to cover at least one semiconductor chip. Laser is projected to the packaging layer between two adjacent semiconductor chips, and a plurality of spot-like depressions are formed on the packaging layer. In addition, a force is applied to the packaging layer to break the packaging layer along the spot-like depressions and form a plurality of semiconductor package units.

An embodiment of the invention provides a semiconductor package unit. The semiconductor package unit includes: a substrate including a front side surface, a back side surface, and a plurality of side surfaces, the front side surface and the back side surface are opposite to each other, and the side surfaces surround the front side surface and the back side surface; at least one semiconductor chip located on the front side surface of the substrate; a packaging layer disposed on the front side surface of the substrate and covering the semiconductor chip and having a plurality of sides; and a sawtoothed structure or a conical structure including a plurality of spot-like depressions and located at at least one of the side surfaces of the substrate and at least one of the sides of the packaging layer.

An embodiment of the invention provides a semiconductor package unit. The semiconductor package unit includes: at least one semiconductor chip; a packaging layer disposed to cover the semiconductor chip and having a plurality of sides; and a sawtoothed structure or a conical structure including a plurality of spot-like depressions and located at at least one of the sides of the packaging layer.

According to an embodiment of the invention, the laser is projected to the same position of the substrate or the packaging layer for one or more times, and the spot-like depressions are formed on the substrate or the packaging layer.

An embodiment of the invention further includes steps as follow. A plurality of cutting lines are defined on the surface of the substrate based on positions of the semiconductor chips, and the spot-like depressions are formed on the substrate or the packaging layer along the cutting lines by using the laser.

According to an embodiment of the invention, the packaging layer includes at least one package and at least one protection layer. The package is in a shape of a semi-sphere, a rectangular body, a polygon, or a planar or curved structure, and the package covers the semiconductor chip, and the protection layer is located at the surface of the substrate where the package is not disposed.

According to an embodiment of the invention, the cutting marks include a plurality of spot-like depressions.

According to an embodiment of the invention, the spot-like depression located at the at least one of the sides of the packaging layer includes a first arc-shaped structure, the spot-like depression located at the at least one of the side surfaces of the substrate includes a second arc-shaped structure, and a radian of the first arc-shaped structure is different from a radian of the second arc-shaped structure.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a side view illustrating a semiconductor package module according to the known art.

FIG. 2 is a top view illustrating a semiconductor package module according to the known art.

FIG. 3 is a top view illustrating a semiconductor package module according to an embodiment of the invention.

FIG. 4 is a side view illustrating a semiconductor package module according to an embodiment of the invention.

FIG. 5 is an enlarged top view illustrating a semiconductor package module according to an embodiment of the invention.

FIG. 6 is an enlarged side view illustrating a semiconductor package module according to an embodiment of the invention.

FIG. 7 is an enlarged side view illustrating a semiconductor package module according to an embodiment of the invention.

FIG. 8 is an enlarged side view illustrating a semiconductor package module according to an embodiment of the invention.

FIG. 9 is a top view illustrating a semiconductor package module according to another embodiment of the invention.

FIG. 10 is a top view illustrating a semiconductor package module according to another embodiment of the invention.

FIG. 11 is a top view illustrating a semiconductor package module according to another embodiment of the invention.

FIG. 12 is a schematic perspective view illustrating a semiconductor package unit according to an embodiment of the invention.

FIG. 13 is a top view illustrating a semiconductor package unit according to an embodiment of the invention.

FIG. 14 is a cross-sectional view illustrating a structure of a portion of a semiconductor package unit according to an embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

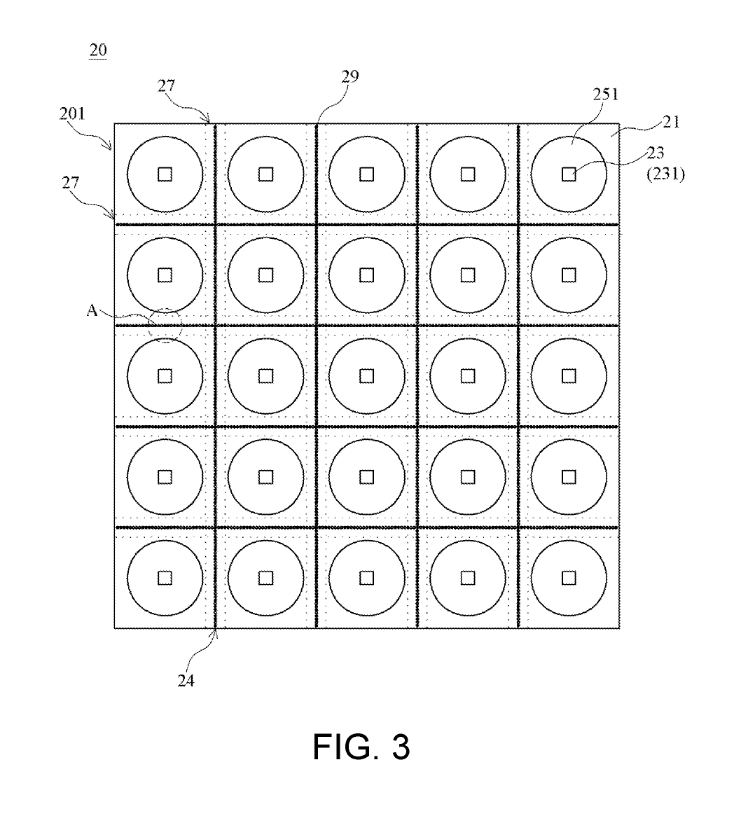

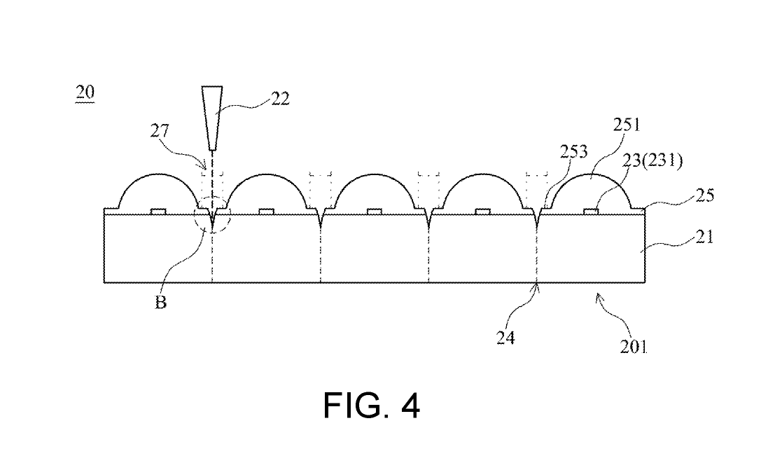

Referring to FIGS. 3 and 4, FIGS. 3 and 4 are respectively a top view and a side view illustrating a semiconductor package module according to an embodiment of the invention. As shown in FIGS. 3 and 4, a semiconductor package module 20 according to an embodiment of the invention includes a substrate 21, a plurality of semiconductor chips 23, and a packaging layer 25, wherein each of the semiconductor chips 23 is disposed on a surface of the substrate 21, and a packaging layer 25 covers each of the semiconductor chips 23 and/or a surface of the substrate 21.

According to an embodiment of the invention, the respective semiconductor chips 23 may be disposed as a matrix on the surface of the substrate 21. For the ease of description, the semiconductor chips 23 in the drawing of the embodiment of the invention are shown in the matrix arrangement. However, the matrix arrangement is merely an embodiment of the invention and shall not be construed as a limitation on the scope of the invention.

In an embodiment of the invention, the semiconductor chip 23 may be an IC chip, a semiconductor device, or a light emitting diode die. In an embodiment of the invention, the substrate 21 may be a Si substrate, an Al₂O₃ substrate, an AlN substrate, a sapphire substrate, an SiC substrate, a printed circuit board (PCB), a ceramic substrate, or a temporary substrate. In an embodiment of the invention, the packaging layer 25 may be formed by silicone, epoxy resin, acrylic resin, photoresist, a transparent or non-transparent encapsulant. In an embodiment of the invention, a fluorescent material, a photoresist material, a protective material, or a heat dissipating material may be added to the packaging layer 25.

In an example where the semiconductor chip 23 is a light emitting diode die 231, the light emitting diode die 231 includes a stack of a P-type material and an N-type material, where a PN junction is formed between the P-type material and the N-type material. In an embodiment of the invention, the N-type material may be formed on the substrate 21, and the P-type material is formed on the N-type material, then, the N-type material and the P-type material are arranged by performing semiconductor manufacturing processes such as an exposure process, a development process, an etching process, and/or the like, so as to form the light emitting diode dies 231 on the substrate. The above-mentioned manufacturing process of the light emitting diode dies 231 is a common technology in the field of the invention and thus will not be further described in the following. Besides, people having ordinary skills in the art may also manufacture the light emitting diode dies 231 based on different processes and methods. In another embodiment of the invention, the light emitting diode dies 231 may also be disposed on the surface of the substrate 21 in a flip-chip manner.

In an embodiment of the invention, an electric circuit (not shown) may be disposed on the substrate 21, and the light emitting diode dies 231 are electrically connected to the electric circuit of the substrate 21. The power or control signal may be supplied to the light emitting diode dies 231 through the electric circuit, so that the light emitting diode dies 231 may emit light. The electric circuit may be disposed on the surface of the substrate 21 or penetrate through the substrate 21. For example, the electric circuit may be formed by forming a plurality of through holes on the substrate 21 and arranging conductive metals in the through holes. The arrangement of the power circuit is also a common technology in the field of the invention, and various arrangements are possible. Therefore, details in this regard will not be further described in the following.

After the light emitting diode dies 231 are formed and connected to the power circuit, the packaging layer 25 may be disposed on the light emitting diode dies 231 and/or the surface of the substrate 21. The packaging layer 25 may include a package 251 and a protection layer 253. As shown in FIG. 4, the package 251 is disposed on each of the light emitting diode dies 231. The package 251 may serve to protect the light emitting diode die 231 and the electric circuit. The package 251 may be in a semi-spherical shape as shown in the figure and converge light generated by the light emitting diode die 231 to generate a light shape as desired. In different embodiments, the package 251 may be embodied as a rectangular body, a planar structure, a curved structure, or a polygon body. In a process of covering the light emitting diode dies 231 with the packaging layer 25, a portion of the packaging layer 25 may flow to the surface of the substrate 21 and form the protection layer 253 on the surface of the substrate 21.

In the drawings and the above description according to the embodiments of the invention, one package 251 is mainly configured to cover one light emitting diode die 231. However, in actual practice, one package 251 may also cover multiple light emitting diode dies 231. For example, the package 251 may be configured to cover multiple light emitting diode dies 231 disposed on the surface of the substrate 21 or cover multiple light emitting diode dies 231 stacked with respect to each other.

After the semiconductor chips 23 and the packaging layer 25 are formed, the semiconductor package module 20 is subjected to a cutting process. The embodiments of the invention mainly adopt a laser 22 to cut the semiconductor package module 20 and thereby form a plurality of individual semiconductor package units 201.

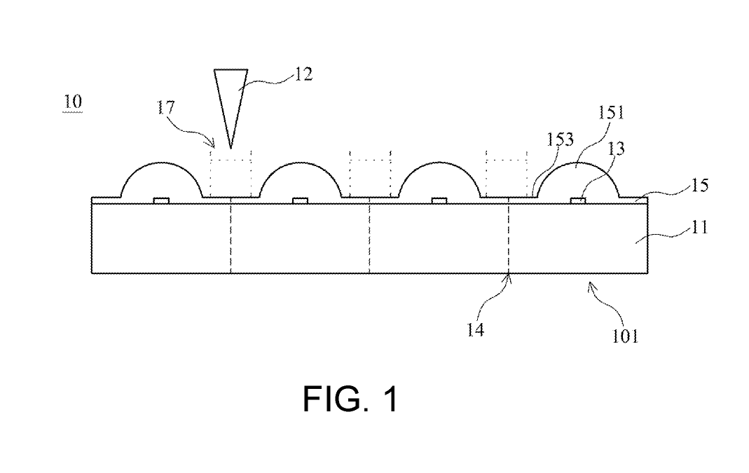

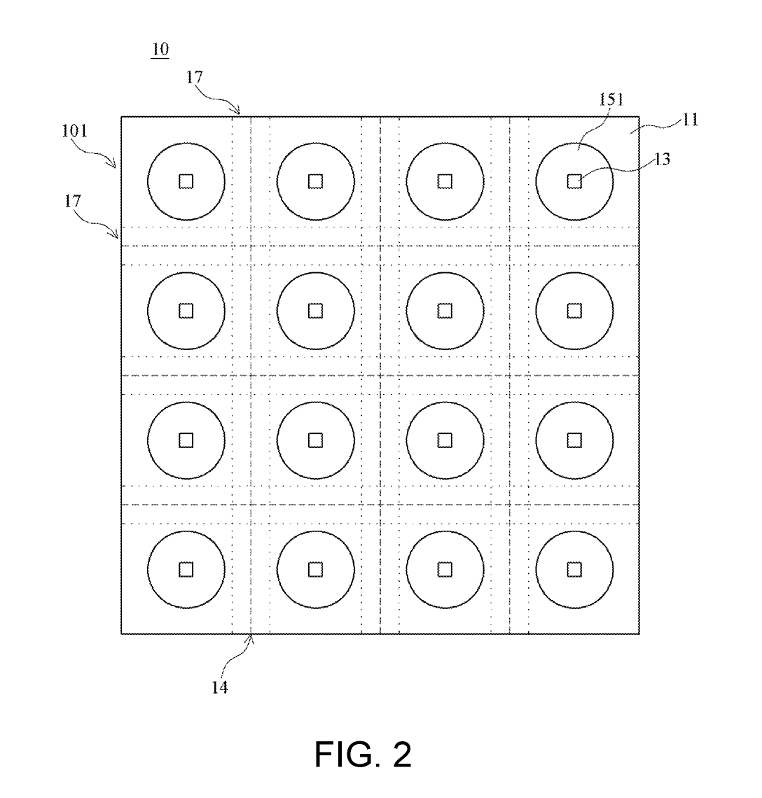

According to the descriptions in “Description of Related Art”, when the light emitting diode dies 13 and the packages 151 are disposed on the surface of the substrate 11, it is common to preserve the cutting channels 17 between the adjacent packages 151 to prevent the packages 151 and/or the light emitting diode dies 13 from being damaged during the cutting process, as shown in FIGS. 1 and 2. However, with the cutting channels 17 disposed, the number of the light emitting diode dies 13 able to be disposed in the same working area on the substrate 11 may be reduced, and the manufacturing efficiency of the light emitting diodes 101 is thus affected.

In the embodiments of the invention, the semiconductor package 20 is cut with the laser 22. Therefore, an area taken up by cutting channels 27 is reduced, or even the area taken up by the cutting channels 27 may be omitted. For example, the width of the cutting channel 27 shown in FIGS. 3 and 4 is clearly shorter than the width of the cutting channel 17 in FIGS. 1 and 2. Therefore, in the same area of the surfaces of the substrates 11 or 21, a greater number of the light emitting diode dies 231 may be disposed, and the manufacturing cost of the light emitting diode dies 231 is relatively reduced. Besides, since the area of the cutting channel 27 is reduced in the embodiments of the invention, the spherical area of the package 251 may be increased accordingly. Therefore, the light emitting efficiency of the semiconductor package units 201 may be facilitated.

However, when the substrate 21 or the packaging layer 25 is cut with the laser 22, a high temperature generated by the laser 22 may burn the substrate 21 or the packaging layer 25. For example, the protection layers 253 and/or the packages 251 may possibly absorb the energy of the laser 22 and be burned, and the yield of the semiconductor package units 201 may be affected. According to the embodiments of the invention, the laser 22 may be projected to the substrate 21 and/or the protection layer 253 of the packaging layer 25 between the adjacent semiconductor chips 23, and a plurality of spot-like depressions 29 are formed on the substrate 21 and/or the packaging layer 25, so as to reduce the chance that the packaging layer 25 is burned and the burned area.

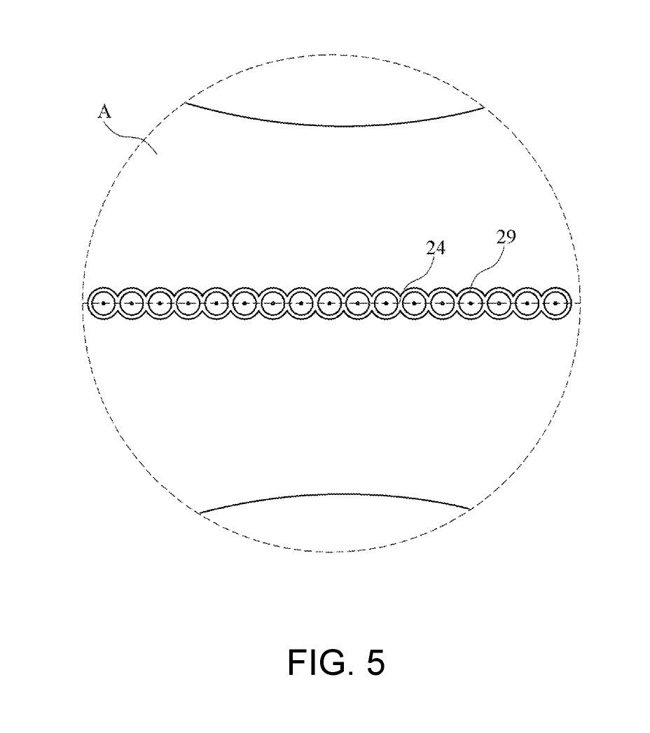

When the semiconductor package module 20 is cut with the laser 22, a plurality of cutting lines 24 may be defined on the surface of the substrate 21 based on positions of the semiconductor chips 23. The cutting lines 24 are virtual lines located between the semiconductor chips 23, and the laser 22 is projected on and move along the cutting lines 24, so as to form the spot-like depressions 29 on the substrate 21 and/or the packaging layer 25. For example, the semiconductor chips 23 on the substrate 21 may be arranged in a matrix, and the cutting lines 24 may be arranged to be chessboard-like. When the laser 22 moves along the cutting lines 24, the laser 22 may be turned on and off based on a predetermined cycle or frequency, or the energy of the laser 22 may be increased and decreased based on a predetermined cycle or frequency. Accordingly, multiple discontinuous spot-like depressions 29 are formed along the cutting lines 24 on the surface of the substrate 21, as shown in FIG. 5. The region A in FIG. 5 corresponds to the region A in FIG. 3.

Since the laser 22 is not continuously turned on or maintained in a high-energy state for a long period of time when cutting the substrate 21 and/or the packaging layer 25 of the semiconductor package module 20, the chance that the protection layers 253 and/or the packages 251 of the packaging layer 25 are burned and the burned area are able to be reduced. Besides, the area of the cutting channels 27 may be further reduced, or the cutting channels 27 may even be omitted. Therefore, a greater number of the semiconductor chips 23 may be disposed in a unit area of the surface of the substrate 21, and the number of the semiconductor package units 201 yielded will be increased.

In an embodiment of the invention, the packaging layer 25 may be uniformly disposed on the surface of the substrate 21 and cover the semiconductor chips 23. Then, the spot-like depressions 29 are formed on the packaging layer 25 and the substrate 21 by using the laser 22. Then, the semiconductor package module 20 and/or the substrate 21 may be broken along the spot-like depressions 29 to form the semiconductor package units 201. The appearance of the packaging layer 25 of the semiconductor package unit 201 manufactured accordingly may be formed as a rectangular body.

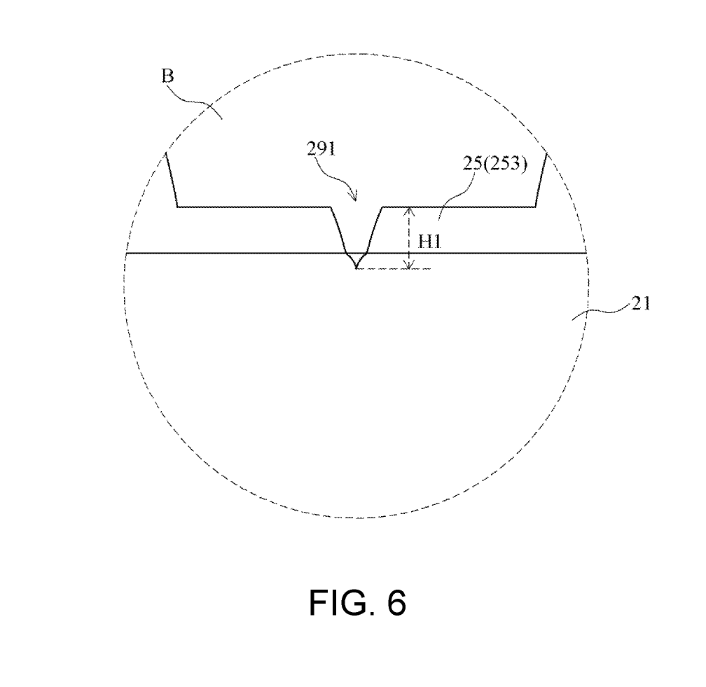

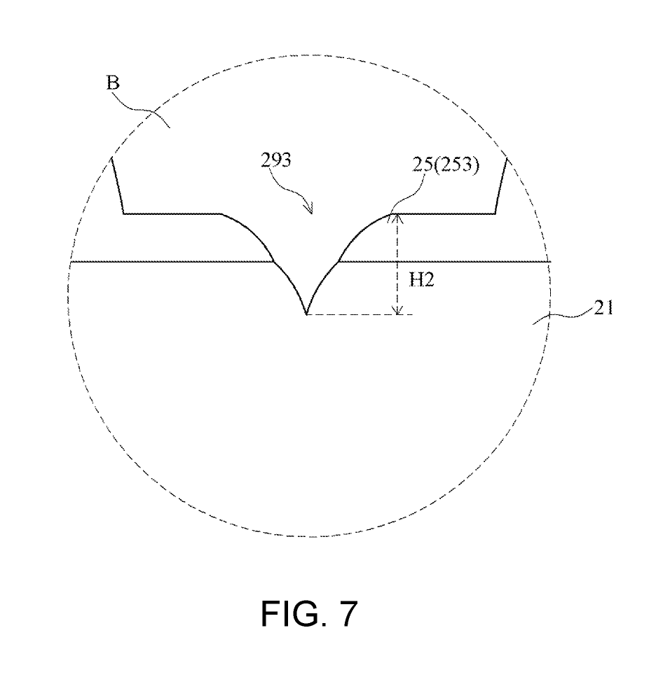

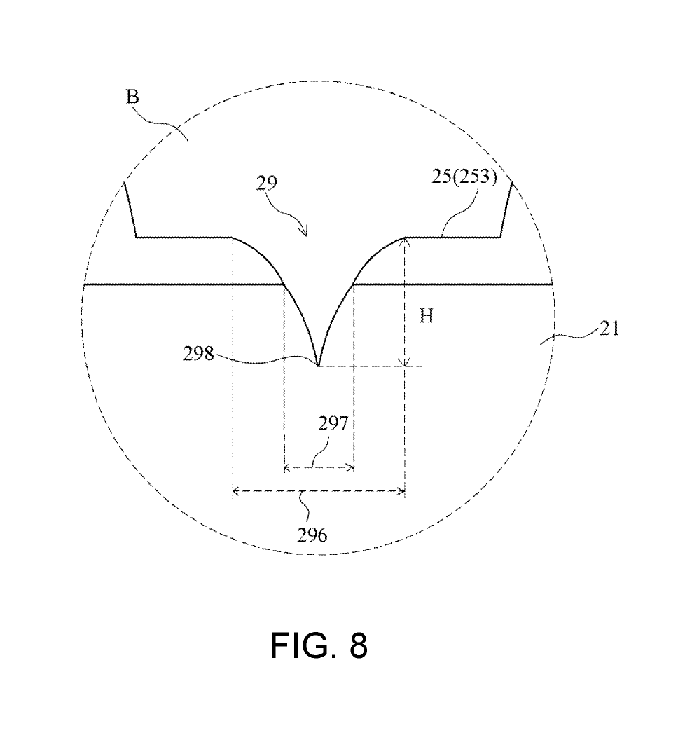

According to an embodiment of the invention, the laser 22 may be spotted for one or more times on the same position of the substrate 21 and/or the packaging layer 25 along the cutting lines 24, so as to form the spot-like depressions 29 on the substrate 21 and/or the packaging layer 25. Specifically, a first spot-like depression 291 having a first depth H1 may be formed on the substrate 21 and/or the packaging layer 25 by using the laser 22, as shown in FIG. 6. After a period of time, the laser 22 is projected again to the first spot-like depression 291 on the substrate 21 and/or the packaging layer 25 to form a second spot-like depression 293 having a second depth H2 on the substrate 21 and/or the packaging layer 25. In addition, the second depth H2 is greater than the first depth H1, as shown in FIG. 7. The step may be repetitively performed until the depth of the spot-like depression 29 on the substrate 21 and/or the packaging layer 25 reaches a predetermined depth H, as shown in FIG. 8. In the embodiment, the spot-like depression 29 is formed by projecting the laser 22 to the substrate 21 and/or the packaging layer 25 for three times. However, the number of times of projection according to the embodiments of the invention is not limited to three. In practical use, the spot-like depression 29 may be formed by projecting the laser for once, twice, three times, or more than three times.

Specifically, the laser 22 may have a single wavelength and a single energy intensity, and is spotted to the substrate 21 and/or the packaging layer 25 in separate sessions to form the spot-like depression 29. Besides, the laser 22 may also have different wavelengths and different energy intensities, and may also be spotted on the substrate 21 and/or the packaging layer 25 in separate sessions to form the spot-like depression 29.

Since the first spot-like depression 291, the second spot-like depression 293, and the spot-like depression 29 are formed on the substrate 21 and/or the packaging layer 25 by using the laser 22 in separate sessions, there are certain time intervals among time points when the first spot-like depression 291, the second spot-like depression 293, and the spot-like depression 29 are formed. Therefore, the laser 22 is projected to the same position after the substrate 21 and/or the packaging layer 25 is cooled off, and the chance that the protection layers 253 and/or the packages 251 of the packaging layer 25 is burned and the burned area may be further reduced and/or eliminated.

Specifically, the spot-like depressions 29 according to the embodiments of the invention do not penetrate through the substrate 21. Therefore, after the spot-like depressions 29 are formed, the substrate 21 is not broken along the spot-like depressions 29 or the cutting lines 24. After the spot-like depressions 29 are formed on all the cutting lines 24, a force may be applied to the substrate 21 to break the substrate 21 of the semiconductor package module 20 along the cutting lines 24 and thereby form the semiconductor package units 201 that are cut.

In an embodiment of the invention, a cross-section of the spot-like depression 29 formed on the substrate 21 and/or the packaging layer 25 by using the laser 22 may be an arc-shaped structure, as shown in FIGS. 6 to 8. The region B in FIGS. 6 to 8 corresponds to the region B in FIG. 4. The spot-like depression 29 having an arc-shaped structure is a main characteristic of the semiconductor package unit 201 manufactured based on the cutting method according to the embodiments of the invention.

In an embodiment of the invention, the spot-like depression 29 may be divided into a protection layer depression 29 broken at the protection layer 253, a substrate depression 297 broken at the substrate 21, and a laser spot depression 298 marking an end point of laser cutting. In addition, a working width at the top of the protection layer depression 296 is in a range from about 1 um to 500um, a working width at the top of the substrate depression 297 is in a range from about 1 um to 150 um, and a working width of the laser spot depression 298 is in a range from about 1 um to 100 um. The working area and the working width of 0.01 um to 100 um of the spot-like depression 29 according to the embodiments of the invention formed when a force is applied to the substrate 21 to break the substrate 21 of the semiconductor package module 20 along the cutting lines 24 are very small and may even be ignored. In the known semiconductor package module, each semiconductor package unit (e.g., the semiconductor package unit 101 or the semiconductor package unit 201) requires to preserve the position of a cutting channel (e.g., the cutting channel 17) in addition to a working width for a protection layer (e.g., the protection layer 153 or the protection layer 253). In the embodiments of the invention, the cutting channel (e.g., the cutting channel 17) does not need to be preserved or used, and the whole laser processing is performed within a vertical working area of the original protection layer (e.g., the protection layer 153 or the protection layer 253). Therefore, a greater number of semiconductor chips (e.g., the semiconductor chips 13 or the semiconductor chips 23) may be disposed in the same area of a substrate (e.g., the substrate 11 or the substrate 21), and a greater number of semiconductor package units (e.g., the semiconductor package units 101 or the semiconductor package units 201) may be yielded.

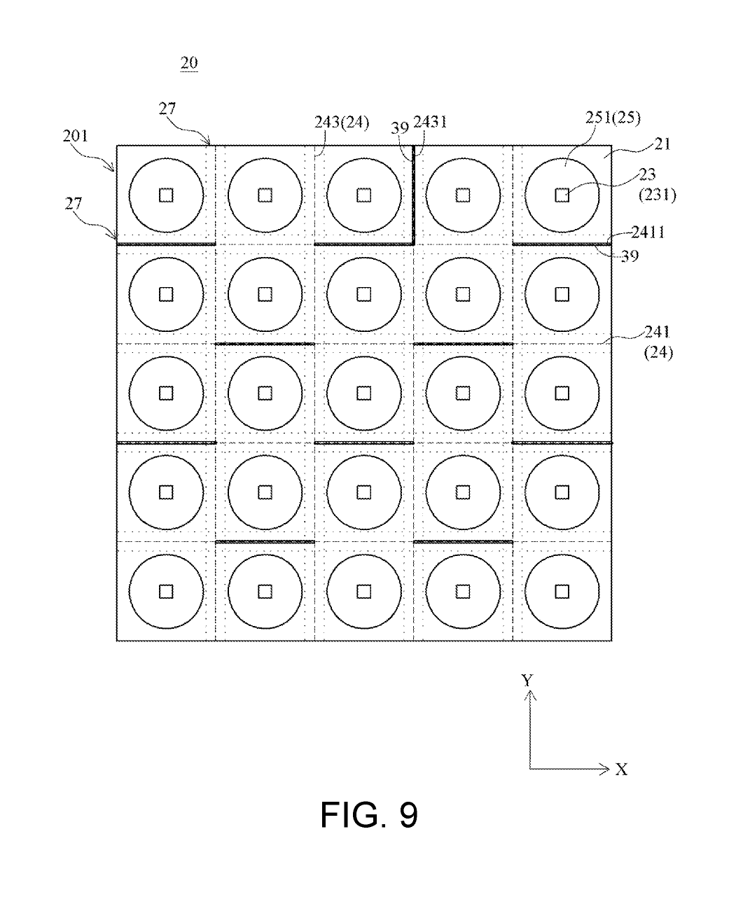

Referring to FIG. 9, FIG. 9 is a top view illustrating a semiconductor package module according to another embodiment of the invention. As shown in FIG. 9, a semiconductor package module 20 according to an embodiment of the invention includes a substrate 21, a plurality of semiconductor chips 23, and a packaging layer 25, wherein each of the semiconductor chips 23 is disposed on a surface of the substrate 21, and the packaging layer 25 covers each of the semiconductor chips 23 and/or the surface of the substrate 21.

Based on the positions of the semiconductor chips 23 on the surface of the substrate, the cutting lines 24 may be defined on the surface of the substrate 21. In addition, the cutting lines 24 are virtual lines. Each of the cutting lines 24 is located between two adjacent semiconductor chips 23. In addition, each of the cutting lines 24 includes a plurality of cutting sections (e.g., a first cutting section 2411 and a second cutting section 2431).

In an embodiment of the invention, the cutting lines 24 defined on the surface of the substrate 21 may include a plurality of first cutting lines 241 parallel to a first direction X and a plurality of second cutting lines 243 parallel to a second direction Y. In addition, the respective first cutting lines 241 respectively interlace the respective second cutting lines 243, and the semiconductor chips 23 are located at regions formed by two adjacent first cutting lines 241 and two adjacent second cutting lines 243. The laser 22 may cut the semiconductor package module 20 and/or the substrate 21 along the virtual cutting lines 24. In an embodiment of the invention, the first cutting lines 241 and the second cutting lines 243 may be perpendicular to each other and form a chessboard-like structure on the substrate 21. In addition, the respective semiconductor chips 23 are located in regions in the chessboard. The first cutting lines 241 and the second cutting lines 243 being perpendicular to each other is only described herein as an example and shall not be construed as a limitation on the scope of the invention.

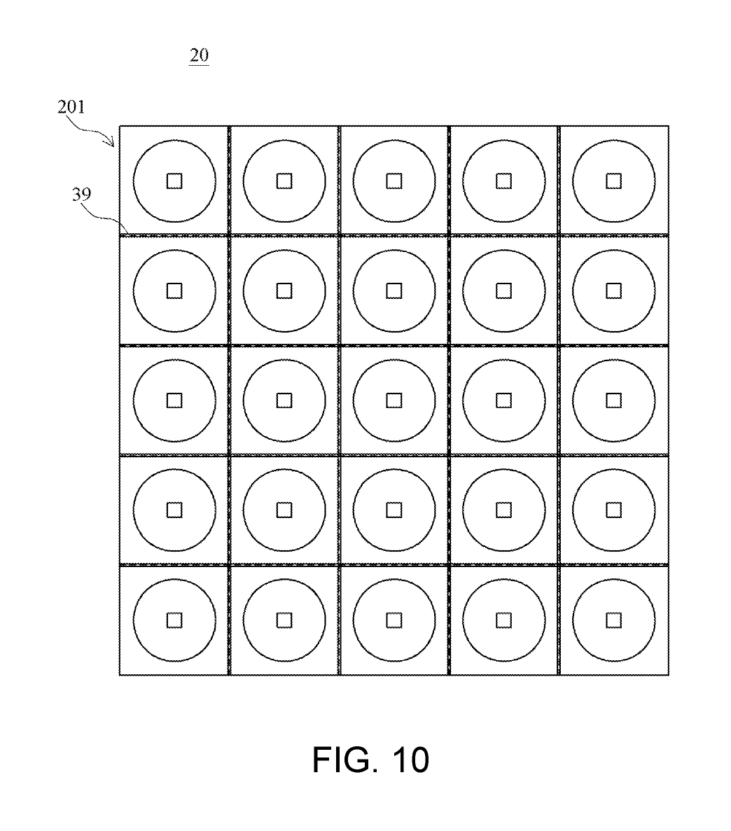

Each of the cutting lines 24 may include a plurality of cutting sections (e.g., the first cutting section 2411 or the second cutting section 2431). For example, the first cutting line 241 includes multiple first cutting sections 2411, and the second cutting line 243 includes multiple second cutting sections 2431. To reduce the chance that the packaging layer 25 is burned by the laser 22 and the burned area, the laser 22 in the embodiment of the invention is sequentially projected to the substrate 21 and/or the packaging layer 25 in non-adjacent cutting sections (e.g., the first cutting section 2411 and the second cutting section 2431), and sequentially forms a plurality of discontinuous cutting marks 39 on the substrate 21 and/or the packaging layer 25 in non-adjacent cutting sections (e.g., the first cutting section 2411 and the second cutting section 2431), until the cutting marks 39 are formed on all the cutting lines 24 by the laser 22, as shown in FIG. 10.

In the drawing of the embodiment of the invention, the first cutting section 2411 is located on the first cutting line 241 and between two adjacent second cutting lines 243, while the second cutting section 2431 is located on the second cutting line 243 and between two adjacent first cutting lines 241. However, in practice, lengths of the first cutting section 2411 and the second cutting section 2431 are not limited to intervals between two adjacent first cutting lines 241 and two adjacent second cutting lines 243, and may be greater or less than the intervals between the first cutting lines 241 and the second cutting lines 243.

When the cutting marks 39 are formed on all the cutting lines 24, a force may be applied to the substrate 21. Accordingly, the substrate 21 of the semiconductor package module 20 may be broken along the cutting lines 24 to form the cut semiconductor package units 201.

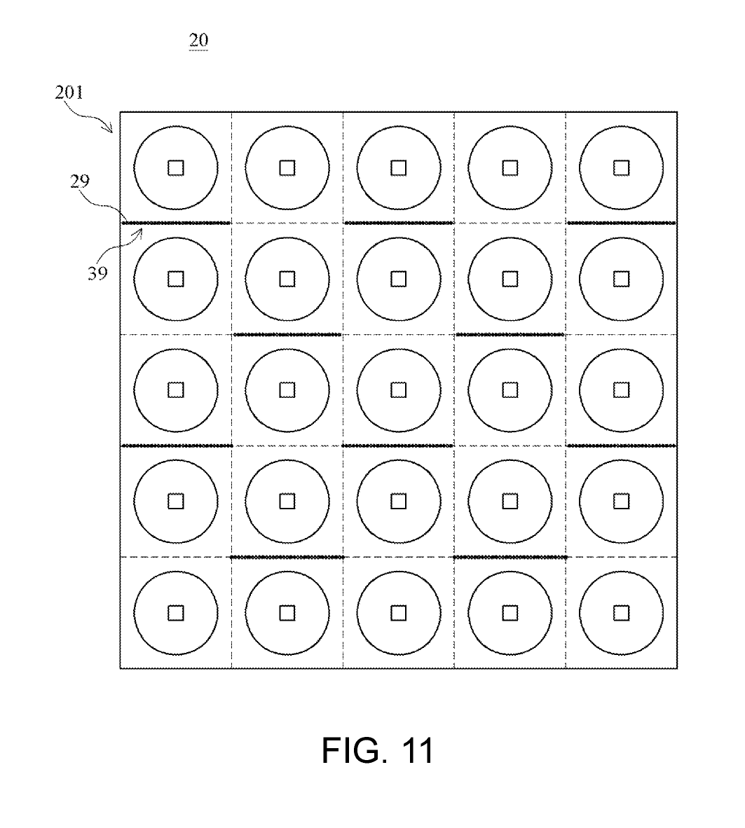

In another embodiment of the invention, one cutting mark 39 may be formed through formation of multiple spot-like depressions 29 based on the method shown in FIGS. 3 to 8, as shown in FIG. 11. The laser 22 may be sequentially projected to non-adjacent cutting sections (e.g., the first cutting section 2411 and the second cutting section 2431), and the multiple spot-like depressions 29 are sequentially formed in non-adjacent cutting sections (e.g., the first cutting section 2411 and the second cutting section 2431) to form the cutting marks 39 of the embodiment, until the multiple spot-like depressions 29 are formed on all the cutting lines 24 and the structure shown in FIG. 3 is formed. How the spot-like depressions 29 are formed is as shown in FIGS. 3 to 8.

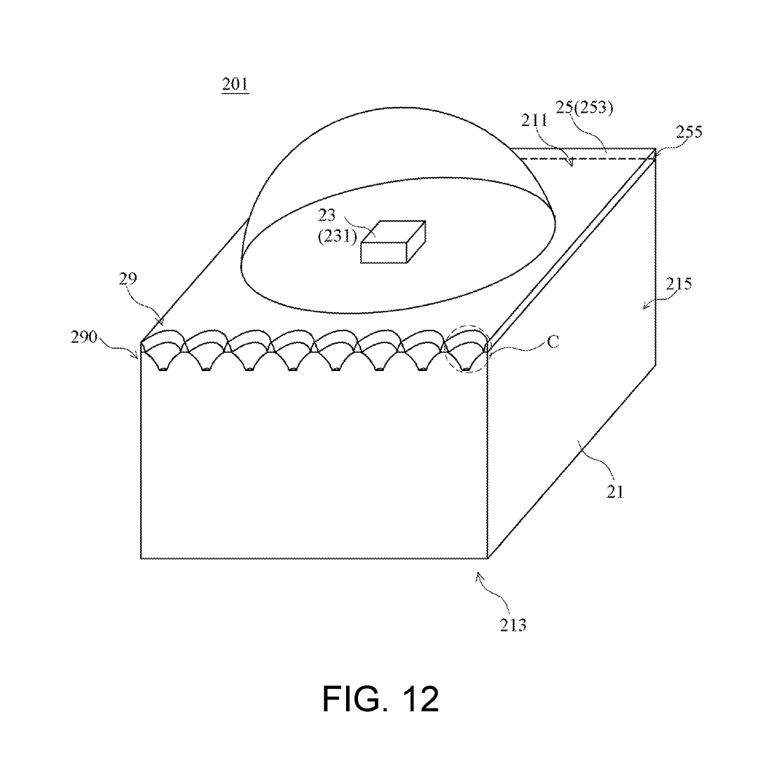

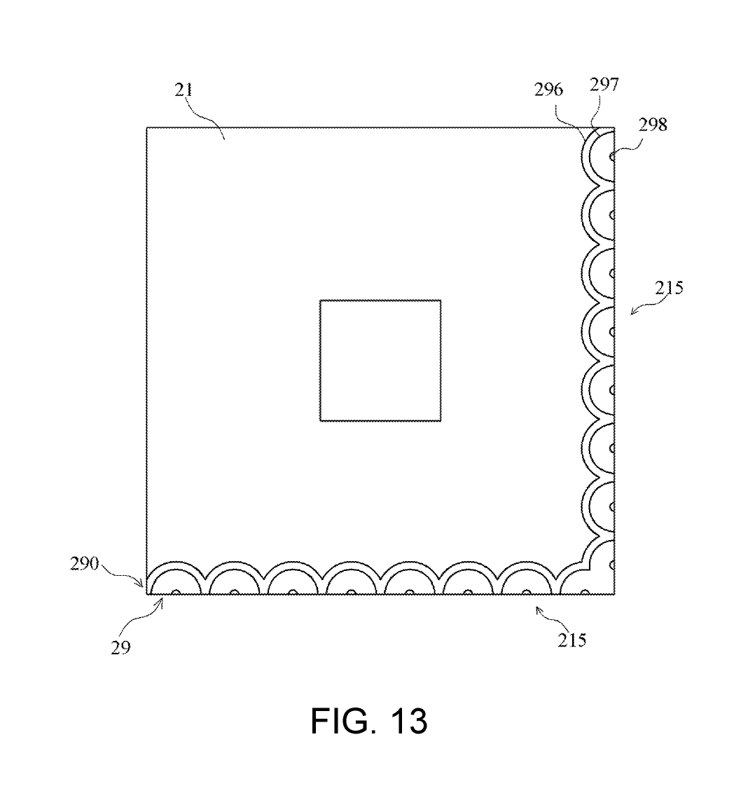

Referring to FIGS. 12 and 13, FIGS. 12 and 13 are respectively a schematic perspective view and a top view illustrating a semiconductor package unit according to an embodiment of the invention. As shown in FIGS. 12 and 13, the semiconductor package unit 201 includes the substrate 21, at least one semiconductor chip 23, and the packaging layer 25, wherein the substrate 21 includes a front side surface 211, a back side surface 213, and a plurality of side surfaces 215. The front side surface 211 is opposite to the back side surface 213, and the plurality of side surfaces 215 are disposed at sides of the front side surface 211 and/or the back side surface 213.

The semiconductor chip 23 is disposed on the front side surface 211 of the substrate 21, and the packaging layer 25 covers the semiconductor chip 23 and the front side surface 211 of the substrate 21. In an embodiment of the invention, the packaging layer 25 includes the package 251 and the protection layer 253, wherein the package 251 is configured to cover the semiconductor chip 23, and the protection layer 253 is disposed on a portion of the front side surface 211 of the substrate 21. In addition, the packaging layer 25 disposed on the front side surface 211 of the substrate 21 includes a plurality of sides 255.

In the semiconductor package unit 201 manufactured according to the cutting method according to the embodiment of the invention, a sawtoothed or conical structure is formed on at least one side surface 215 of the substrate 21 and at least one side 255 of the packaging layer 25. For example, FIG. 13 illustrates a sawtoothed structure. Specifically, when the semiconductor package module 20 is broken along the spot-like depressions 29 and/or the cutting lines 24, a sawtoothed structure 290 is formed accordingly on at least one side of the semiconductor package unit 201, and the sawtoothed structure 290 is formed by multiple spot-like depressions 29.

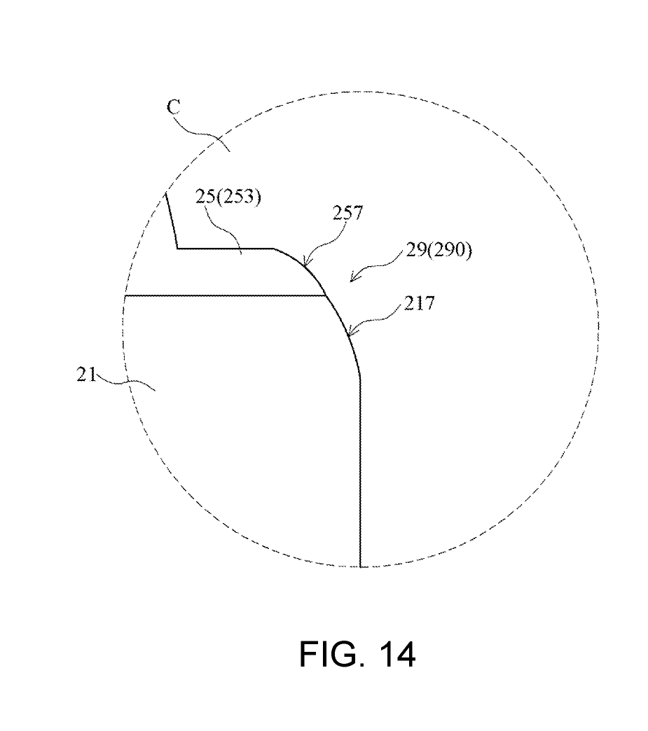

FIG. 14 is a schematic cross-sectional view illustrating the spot-like depression 29 and/or the sawtoothed structure 290 of the semiconductor package unit 201. The region C in FIG. 14 is an enlarged cross-sectional schematic view corresponding to the region C in FIG. 12. At least one side 255 of the packaging layer 25 has a first arc-shaped structure 257, and at least one side surface 215 of the substrate 21 has a second arc-shaped structure 217, wherein the first arc-shaped structure 257 and the second arc-shaped structure 217 may have different radian or different radii of curvature.

In yet another embodiment of the invention, the light emitting diode dies 231 may also be disposed on a surface of a temporary substrate 21. The laser 22 is projected on the package 251 between two adjacent semiconductor chips 23 and form the spot-like depressions on the package 251. Then, the temporary substrate is removed, and then a force is applied to the package 251 to break the package 251 along the spot-like depressions 29. Accordingly, the semiconductor package units 201 having only the semiconductor chips 23 and the packaging layer 25 and not having the substrate 21 are formed.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A cutting method of a semiconductor module, comprising:
disposing a plurality of semiconductor chips on a surface of a substrate;
covering the semiconductor chips disposed on the surface of the substrate with a packaging layer;
projecting laser to the substrate or the packaging layer between two adjacent semiconductor chips, and forming a plurality of spot-like depressions on the substrate or the packaging layer; and
applying a force to the substrate to break the substrate along the spot-like depressions and form a plurality of semiconductor package units.

2. The cutting method of the semiconductor module as claimed in claim 1, further comprising: projecting the laser to the same position of the substrate or the packaging layer for one or more times, and forming the spot-like depressions on the substrate or the packaging layer.

3. The cutting method of the semiconductor module as claimed in claim 1, further comprising: defining a plurality of cutting lines on the surface of the substrate based on positions of the semiconductor chips, projecting the laser to the cutting lines, and forming the spot-like depressions on the substrate or the packaging layer along the cutting lines.

4. The cutting method of the semiconductor module as claimed in claim 1, wherein the semiconductor chip is a light emitting diode die, an IC chip, or a semiconductor device.

5. The cutting method of the semiconductor module as claimed in claim 1, wherein the packaging layer comprises at least one package and at least one protection layer, the package is in a shape of a semi-sphere, a planar body, a rectangular body, a polygon, or a curved structure, and the package covers the semiconductor chip, and the protection layer is located at the surface of the substrate where the package is not disposed.

6. A cutting method of a semiconductor module, comprising:
disposing a plurality of semiconductor chips on a surface of a substrate;
covering the semiconductor chips on the surface of the substrate with a packaging layer;
defining a plurality of cutting lines on the surface of the substrate based on positions of the semiconductor chips, wherein each of the cutting lines is located between two semiconductor chips, and each of the cutting lines comprises a plurality of cutting sections;
sequentially projecting laser on the substrate or the packaging layer in non-adjacent cutting sections, and sequentially forming a plurality of cutting marks on the substrate or the packaging layer in the non-adjacent cutting sections until the cutting marks are formed on all the cutting lines by the laser; and
applying a force to the substrate to break the substrate along the cutting marks and form a plurality of semiconductor package units.

7. The cutting method of the semiconductor module as claimed in claim 6, wherein the cutting marks comprise a plurality of spot-like depressions.

8. The cutting method of the semiconductor module as claimed in claim 7, further comprising: projecting the laser to the same position of the substrate or the packaging layer for one or more times, and forming the spot-like depressions on the substrate or the packaging layer.

9. The cutting method of the semiconductor module as claimed in claim 6, wherein the semiconductor chip is a light emitting diode die, an IC chip, or a semiconductor device.

10. The cutting method of the semiconductor module as claimed in claim 6, wherein the packaging layer comprises at least one package and at least one protection layer, the package is in a shape of a semi-sphere, a planar body, a rectangular body, a polygon, or a curved structure, and the package covers the semiconductor chip, and the protection layer is located at the surface of the substrate where the package is not disposed.

11. A semiconductor package unit, comprising:
a substrate, comprising a front side surface, a back side surface, and a plurality of side surfaces, wherein the front side surface and the back side surface are opposite to each other, and the side surfaces surround the front side surface and the back side surface;
at least one semiconductor chip, located on the front side surface of the substrate;
a packaging layer, disposed on the front side surface of the substrate and covering the semiconductor chip and having a plurality of sides; and
a sawtoothed structure or a conical structure, comprising a plurality of spot-like depressions and located at least one of the side surfaces of the substrate and at least one of the sides of the packaging layer.

12. The semiconductor package unit as claimed in claim 11, wherein the spot-like depression located at the at least one of the sides of the packaging layer comprises a first arc-shaped structure, the spot-like depression located at the at least one of the side surfaces of the substrate comprises a second arc-shaped structure, and a radian of the first arc-shaped structure is different from a radian of the second arc-shaped structure.

13. A cutting method of a semiconductor module, comprising:
disposing a packaging layer to cover at least one semiconductor chip;
projecting laser to the packaging layer between two adjacent semiconductor chips, and forming a plurality of spot-like depressions on the packaging layer; and
applying a force to the packaging layer to break the packaging layer along the spot-like depressions and form a plurality of semiconductor package units.

14. A semiconductor package unit, comprising:
at least one semiconductor chip;
a packaging layer, disposed to cover the semiconductor chip and having a plurality of sides; and
a sawtoothed structure or a conical structure, comprising a plurality of spot-like depressions and located at at least one of the sides of the packaging layer, wherein the spot-like depression comprises a first arc-shaped structure.
